(19) United States
(12) Patent Application Publication
(10) Pub. No.: US 2009/0243672 A1
(43) Pub. Date: Oct. 1, 2009

(54) MULTI-POLE DELAY ELEMENT DELAY LOCKED LOOP (DLL)

(76) Inventors: Guneet Singh, Santa Clara, CA (US); Roan M. Nicholson, San Jose, CA (US); Frank O'Mahony, Portland, OR (US)

Correspondence Address: RYDER IP LAW;C/O CPA Global, P. O. BOX 52050, MINNEAPOLIS, MN, 55402, US

(21) Appl. No.: 12/060,245

(22) Filed: Mar. 31, 2008

(51) Int. Cl. H03L 7/06; H03H 11/16

(52) U.S. Cl. 327/157; 327/231

(57) ABSTRACT

In general, in one aspect, the disclosure describes a delay line including a cascade of delay stages where each stage delays the phase a defined amount. Each delay stage includes an active voltage control delay element and one or more passive delay elements (e.g., resistive-capacitive (RC) networks). The aggregate amplitude gain roll-off of an active/passive multi pole delay stage delaying the phase a defined amount is less than the amplitude gain roll-off of a single pole delay stage delaying the phase the defined amount. Accordingly jitter amplification of the active/passive multi pole delay stage is less than that of a single pole delay stage. The power consumption of an active/passive multi pole delay stage is less than an all active multi pole delay stage.

### BACKGROUND

Delay Locked Loops (DLLs) can be used to generate equally spaced multiple clock phases. The phase shifts in a DLL are generated using a delay line that includes a cascade of delay stages or elements where each stage delays the phase a defined amount (e.g., 22.5 degrees, 45 degrees, 90 degrees). The delay provided by each stage is created by an active voltage control delay element. The delay element has higher amplitude gain at DC compared to its gain at the operating clock frequency, assuming a single dominant pole system. This difference between DC gain and operating frequency gain (or amplitude gain roll-off) amplifies jitter and duty cycle error. Larger delay per delay stage implies higher amplitude gain roll-off and hence higher jitter amplification. Since the delay stages in a delay line are cascaded, the aggregate amplitude gain roll-off of the whole delay line is much higher compared to a single delay element, which results in even more jitter amplification through the delay line.

Reducing the delay provided by each delay element in the delay line reduces the amplitude roll-off of each delay element and the resulting jitter amplification. However, reducing the amount of delay provided by each delay element requires additional delay elements (stages). Increasing the number of stages increases the power consumption of the DLL. Accordingly, there is a trade-off between jitter amplification and power consumption in the design of DLLs.

### BRIEF DESCRIPTION OF THE DRAWINGS

The features and advantages of the various embodiments will become apparent from the following detailed description in which:

FIG. 1 illustrates an example delay locked loop (DLL), according to one embodiment;

FIG. 2 illustrates an example delay line, according to one embodiment;

FIG. 3 illustrates an example voltage controlled delay element, according to one embodiment;

FIG. 4 illustrates an example two-pole delay line, according to one embodiment;

FIG. 5A illustrates a graph comparing the bandwidth roll-off of a two pole stage and single pole delay stage, according to one embodiment;

FIG. 5B illustrates a graph comparing an example jitter amplification of a single pole four stage delay line to a two pole four stage delay line, according to one embodiment; and

FIG. 6 illustrates a multi-pole delay line, according to one embodiment.

### DETAILED DESCRIPTION

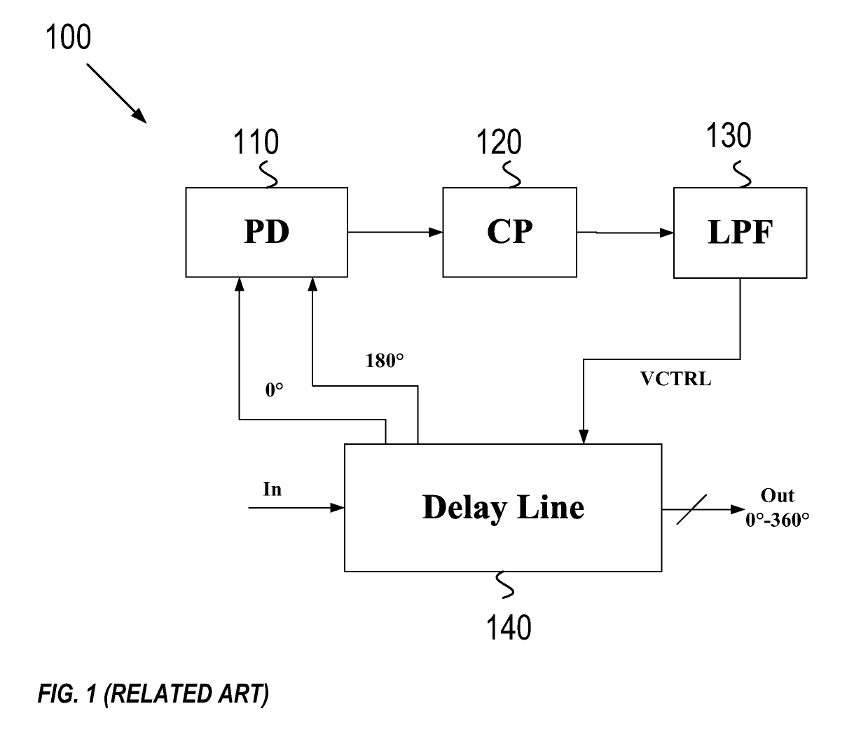

FIG. 1 illustrates an example delay locked loop (DLL) 100. The DLL 100 includes a phase detector (PD) 110, a charge pump (CP) 120, a low pass filter (LPF) 130 and a delay line 140. The delay line 140 receives an incoming differential signal (0°, 180°). The PD 110 generates an UP/DOWN signal by comparing the phase of the input with the signal delayed through the delay line 140. The CP 120 and LPF 130 generate a filtered control voltage signal (VCTRL) for the delay line 140. The delay line 140 generates equiphase clocks from 0°-360° (0 to 2π). The clock phases may be subsequently used for fine phase adjustment (e.g., by a Phase Interpolator) further down stream.

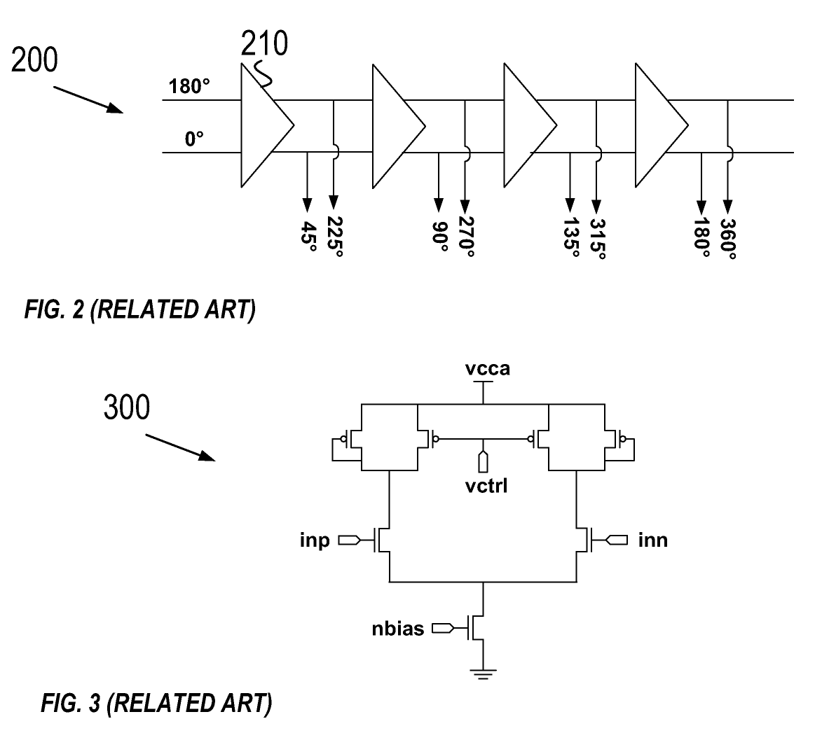

FIG. 2 illustrates an example delay line 200 (e.g., 140 of FIG. 1). The delay line 200 provides the phase shift in stages where each stage includes a voltage controlled delay element 210 (active device). Each delay element 210 provides a phase shift of 45 degrees. The delay element 210 can be approximated as a single pole system. In a single pole system, a 45 degree phase shift results in an amplitude gain roll-off of 3 dB, assuming small signal behavior. As such each stage of the delay line 200, providing 45 degree phase shift, has an amplitude gain roll-off of approximately 3 dB at the operating frequency of the DLL compared to the DC gain. A 3 dB difference between DC Gain and operating frequency implies that duty cycle error in the signal is amplified 3 dB more than the signal, resulting in duty cycle error amplification. Jitter (especially high frequency jitter) like duty cycle error is also amplified. As the delay line 200 includes 4 stages, jitter is amplified in each stage (with successive stages amplifying the previously amplified jitter).

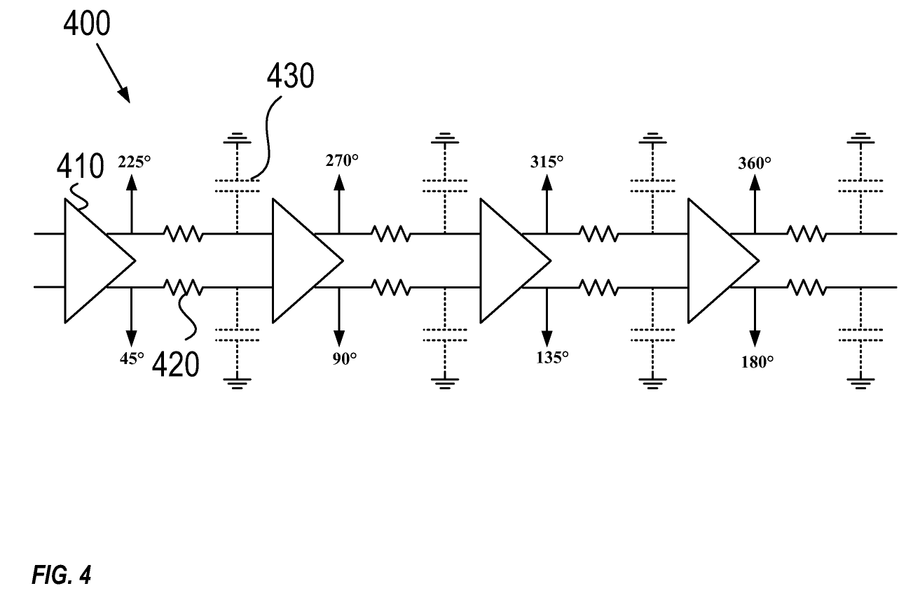

FIG. 3 illustrates an example voltage controlled delay element 300 (e.g., 210 of FIG. 2).

Reducing the phase shift (e.g., from 45° to 30° or a lower number) of each delay element reduces the amplitude roll-off and associated jitter amplification. However, reducing the phase shift requires additional delay elements to generate the 0°-360° clocks (e.g., from 4 to 6). Increasing the number delay elements increases the power of the DLL. Accordingly, there is a tradeoff between jitter amplification and power consumption.

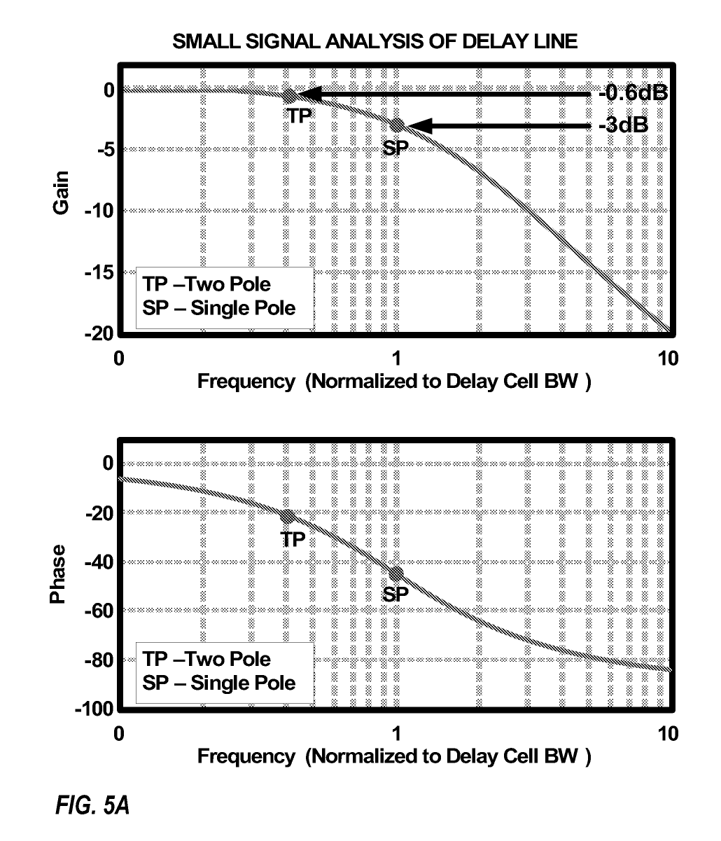

FIG. 4 illustrates an example delay line 400 (e.g., 140 of FIG. 1) that includes an active delay element 410 and a resistor-capacitor (RC) network in each stage of the delay line. The implementation of the delay element 410 may be such as that illustrated in FIG. 3. The RC network is a passive device and includes a resistor 420 and capacitor 430 between delay elements 410 on each leg of the delay line. The delay element 410 acts as a first pole (active pole) and the RC network acts as a second pole (passive pole) for each stage. Each pole generates a portion of the phase shift per stage. For example, a 45 degree phase shift may be realized with each pole (the delay element 410 and the RC network) producing a 22.5 degree phase shift.

The aggregate amplitude gain roll-off of a two pole 45 degree phase shift (two 22.5 degree phase shifts) is substantially less than the amplitude gain roll-off of a single pole 45 degree phase shift. Accordingly jitter amplification of a two pole 45 degree phase shift delay stage is substantially less than that of a single pole 45 degree phase shift delay stage.

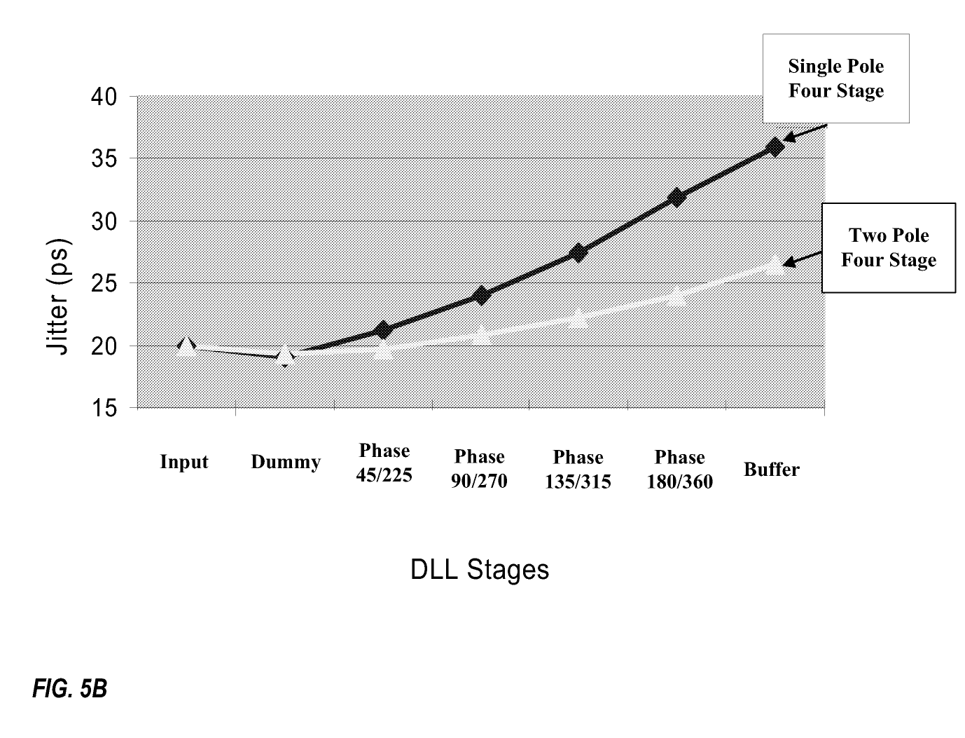

FIG. 5A illustrates a graph comparing an example bandwidth roll-off of a two pole delay stage and single pole delay stage. The single pole delay stage providing a 45 degree phase shift may result in an amplitude roll-off of 3 dB whereas the two pole delay stage providing a total shift of 45 degrees may result in an aggregate amplitude roll-off of only 1.2 dB (0.6 dB per pole).

FIG. 5B illustrates a graph comparing an example jitter amplification of a single pole four stage delay line to a two pole four stage delay line (e.g., 400 of FIG. 4). As illustrated, the difference between the jitter amplification for the single pole and two pole delay lines becomes greater as the signal passes through each delay stage and the jitter is further amplified. As illustrated, the jitter started as 20 psec and was amplified to approximately 36 psec (approximately 80% amplification) for the single pole delay line and was amplified to approximately 26 psec (approximately 30% amplification) for the two stage delay line.

It should be noted that the same jitter amplification performance as that illustrated in FIG. 5B for the delay line 400 may be achieved by using two active poles per 45 degree phase shift rather than one active pole and one RC network, but at the cost of doubling power consumption.

Referring back to FIG. 4, a discrete capacitor 430 may not be necessary in the RC network since the input gate capacitance (plus metal routing parasitic capacitances) of the delay element 410 for the next delay stage may serve as the capacitance of the second pole (RC network). The resistor 420 may be a block silicide resistor (BSR). If passive resistors, such as BSRs, are not available then transistor pass-gates may be used.

The implementation of the RC network as a passive pole (second pole) in the delay stage reduces jitter amplification with minimal power and area penalty. The power and area penalty is less than the penalty for an active only implementation with two poles (and half the phase shift per stage) that can also reduce jitter amplification by a similar amount, but comes with the cost of doubling the power consumption. The RC network can be implemented with minimal impact or modifications to current DLL architectures.

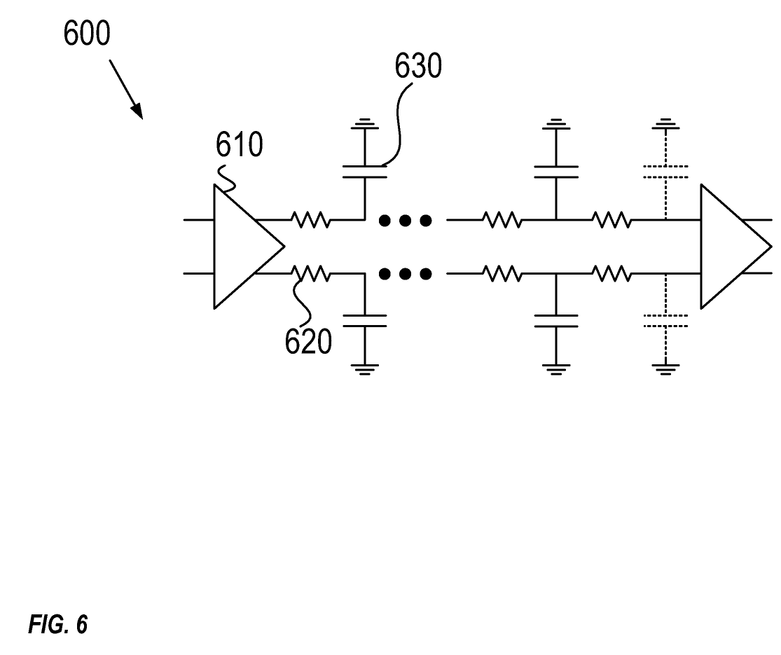

FIG. 6 illustrates a single stage of a multi-pole delay line 600. The stage of the delay line 600 includes a delay element 610 and a plurality of RC networks (resistor 620, capacitor 630). The RC networks each act as a passive pole and provide a portion of the phase shift. As the phase shift provided by each pole is reduced, the aggregate amplitude gain roll-off of the delay line is reduced and hence jitter amplification is reduced. The multi-pole delay line 600 may include discrete capacitances 630 for all the passive poles except the passive pole right before the next delay element 610 that may receive the capacitance therefrom.

The multi-pole delay lines 400, 600 combine active and passive (e.g., RC networks) poles in each stage to reduce aggregate amplitude gain roll-off and hence reduce jitter amplification. A delay line with only active poles may provide similar jitter amplification performance as the delay lines 400, 600 but at the cost of higher power consumption. Accordingly, multi-pole delay lines 400, 600 (with one active pole and one or more passive poles per delay element) can overcome a fundamental trade off between jitter amplification and power consumption. The multi-pole delay lines 400, 600 enable reduced power consumption for jitter sensitive applications, like high speed dense input/output (I/O) systems, where localized DLLs are required to drive multiple receiver channels. The multi-pole delay lines 400, 600 may also enable jitter to be managed as I/O clock frequency increases without requiring excessive power consumption which is not a very practical solution.

Although the disclosure has been illustrated by reference to specific embodiments, it will be apparent that the disclosure is not limited thereto as various changes and modifications may be made thereto without departing from the scope. Reference to “one embodiment” or “an embodiment” means that a particular feature, structure or characteristic described therein is included in at least one embodiment. Thus, the appearances of the phrase “in one embodiment” or “in an embodiment” appearing in various places throughout the specification are not necessarily all referring to the same embodiment.

The various embodiments are intended to be protected broadly within the spirit and scope of the appended claims.

What is claimed:

1. A delay line comprising
a plurality of cascading delay stages, wherein each delay stage delays the phase of a clock signal a defined amount, wherein each stage includes an active delay device and one or more passive delay devices.

2. The delay line of claim 1, wherein use of the one or more passive delay devices with the active delay device reduces jitter amplification of the delay line with limited power consumption penalty.

3. The delay line of claim 1, wherein the passive delay device is a resistive-capacitive (RC) network.

4. The delay line of claim 3, wherein the RC network is coupled between the active delay device of successive delay stages.

5. The delay line of claim 4, wherein a next delay stage provides capacitance of the RC network.

6. The delay line of claim 4, wherein the RC network includes a block silicide resistor (BSR).

7. The delay line of claim 4, wherein the RC network includes a discrete capacitor.

8. A delay locked loop (DLL) comprising
a phase detector;
a charge pump;
a low pass filter; and
a multi-pole delay line having a plurality of cascading delay stages, wherein each delay stage delays the phase of a clock signal a defined amount, wherein each stage includes an active delay device and one or more passive delay devices.

9. The DLL of claim 8, wherein use of the one or more passive delay devices with the active delay device reduces jitter amplification of the delay line with limited power consumption penalty.

10. The DLL of claim 8, wherein the multi-pole delay line is jitter sensitive.

11. The DLL of claim 8, wherein the passive delay device is a resistive-capacitive (RC) network.

12. The DLL of claim 11, wherein the RC network is coupled between the active delay devices of consecutive delay stages.

13. The DLL of claim 12, wherein a next delay stage provides capacitance of the RC network in a current delay stage.

14. The DLL of claim 11, wherein the RC network includes a block silicide resistor (BSR).

15. The DLL of claim 11, wherein the RC network includes a discrete capacitor.
